(19) United States
(12) Patent Application Publication
(10) Pub. No.: US 2008/0099874 A1
(43) Pub. Date: May 1, 2008

(54) SEMICONDUCTOR INTEGRATED CIRCUIT CAPABLE OF REALIZING REDUCTION IN SIZE

(75) Inventor: Hiroshi Kumano, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/923,132

(22) Filed: Oct. 24, 2007

(30) Foreign Application Priority Data
Oct. 27, 2006 (JP) 2006-292089

(51) Int. Cl. H01L 29/00

(52) U.S. Cl. 257/506; 257/E29.001

(57) ABSTRACT

In a semiconductor integrated circuit in which an element isolating insulation film is provided on a substrate, an isolated Si region in the substrate is a shape composed of straight lines which form four sides and circular arcs which form four corners. Further, the adjacent Si regions share element isolating insulation films, and the adjacent Si regions are separated by one element isolating insulation film. Furthermore, widths of the element isolating insulation films are the same in a chip pattern. When the width of the element isolating insulation film is set to a, and a curvature radius of curved lines at four corners of the Si region is set to r; the width a and the curvature radius r are determined so as to satisfy conditions of r>0.7a in the case where the element isolating insulation films are intersected only in a cross shape, and r>1.5a in the case where the element isolating insulation films include a portion intersected in a T shape.

### BACKGROUND OF THE INVENTION

1. Field of the Invention

The present invention relates to semiconductor integrated circuits and, more particularly, relates to a semiconductor integrated circuit in which an element isolating insulation film is provided on a substrate.

2. Description of the Related Art

In recent years, flat panel displays (referred to as FPD) such as liquid crystal displays and plasma displays, which can display a high resolution image, have been rapidly accepted in widespread use. With respect to further needs for achieving high resolution and high luminance of the FPD, semiconductor devices having a fast data transfer rate and a high breakdown voltage performance are required for scan drivers and data drivers which are used as a driver application.

In the manufacture of such devices, generally, an integrated circuit in which a plurality of elements are mounted on one chip is formed by forming element isolating insulation films on a substrate. As one of element isolation techniques, there is the deep trench isolation (referred to as DTI) method. In the DTI method, for example, a deep trench is formed in an active region Si of a silicon on insulator (referred to as SOI) substrate along the outer circumference of a region to be separated; and then, an element isolating insulation film is formed by forming an Si oxide film in an inner wall of the trench and by planarizing the surface after Poly-Si is further embedded. An element such as a transistor is formed at each of the Si regions which are electrically separated by the Si oxide film and the Poly-Si.

In the DTI method, a trench of approximately 1 to 3 μm in width and approximately 5 to 30 μm in depth is formed by anisotropic etching such as reactive ion etching (referred to as RIE). If the trench width and the total trench area are variable by element arrangement or the like, etching speed is not uniform in a chip; and as a result, there is a case that the trench depth after etching is varied. At this time, if the trench does not reach an insulation layer of the SOI substrate, the Si region does not become an insulatively separated state. Furthermore, an amount of Poly-Si necessary for embedding differs depending on the trench width; and therefore, there is a case where planarization cannot be uniformly achieved and a concave is generated in the center of the trench.

In order to solve such problem, there is proposed techniques in which each Si region is surrounded by uniform wide trenches, each trench having a closed pattern, so as not to share other Si region with an element isolating insulation film; and an oblique pattern in which corners of an intersecting portion of the trenches are eliminated is formed to form a dummy Si pattern in the intersecting portion (for example, see Japanese Patent Laid Open Publication H5-63073).

In the above techniques, when an element isolating insulation film is not shared between Si regions, a space between the trenches is inevitably required, and the Si regions becomes apart from each other; and therefore, a chip area increases. Furthermore, when the oblique pattern in which the corners of the intersecting portion are eliminated is formed, a stress is concentrated at the end of the oblique pattern by a repulsive force between oxygen atoms which constitute the oxide film formed inside the trench. This allows generating a crystal defect in the aforementioned portion, and allows a variation to generate easily in electrical characteristics such as resistance value. In such a case, elements need to be mounted at a range where no influence of defect due to the stress is exerted; and as a result, an area in each Si region has to be increased, and consequently the chip area increases. In addition, with respect to the trench width, arrangement of the oblique pattern, size and arrangement of the dummy Si pattern, and the like have to be calculated; and therefore, designing is not easy.

### Related Art List

JPA laid open H5-63073

### SUMMARY OF THE INVENTION

The present invention has been made in view of such problem, and it is a general purpose of the present invention to provide a semiconductor integrated circuit which is small in chip area and easy to design.

A certain embodiment of the present invention relates to a semiconductor integrated circuit. The semiconductor integrated circuit includes a layer provided with an embedded line in which a predetermined material is embedded in a trench, and the embedded line has a predetermined width and a pattern thereof includes portions which intersect each other. The embedded line in the intersecting portions includes at least either a curved line portion or a broken line portion which makes one embedded line separate into two directions.

In addition, those in which an arbitral combination of the above constituent elements and representation of the present invention convert between manufacturing methods and semiconductor substrates are also effective as an embodiment of the present invention.

### BRIEF DESCRIPTION OF THE DRAWINGS

FIG. 1 is a view showing one chip pattern and its cross section when element isolating insulation films are formed on an SOI substrate by the DTI method in the present embodiment;

FIG. 2 is an enlarged view showing a portion in which the element isolating insulation films intersect in a cross shape in the chip pattern of the present embodiment;

FIG. 3 is an enlarged view showing a portion in which the element isolating insulation films intersect in a T shape in the chip pattern of the present embodiment;

FIG. 4 is a view for explaining a method of manufacturing the chip pattern in the present embodiment;

FIG. 5 is a view for explaining the method of manufacturing the chip pattern in the present embodiment;

FIG. 6 is a view for explaining the method of manufacturing the chip pattern in the present embodiment;

FIG. 7 is a view for explaining the method of manufacturing the chip pattern in the present embodiment; and

FIG. 8 is a view for explaining the method of manufacturing the chip pattern in the present embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

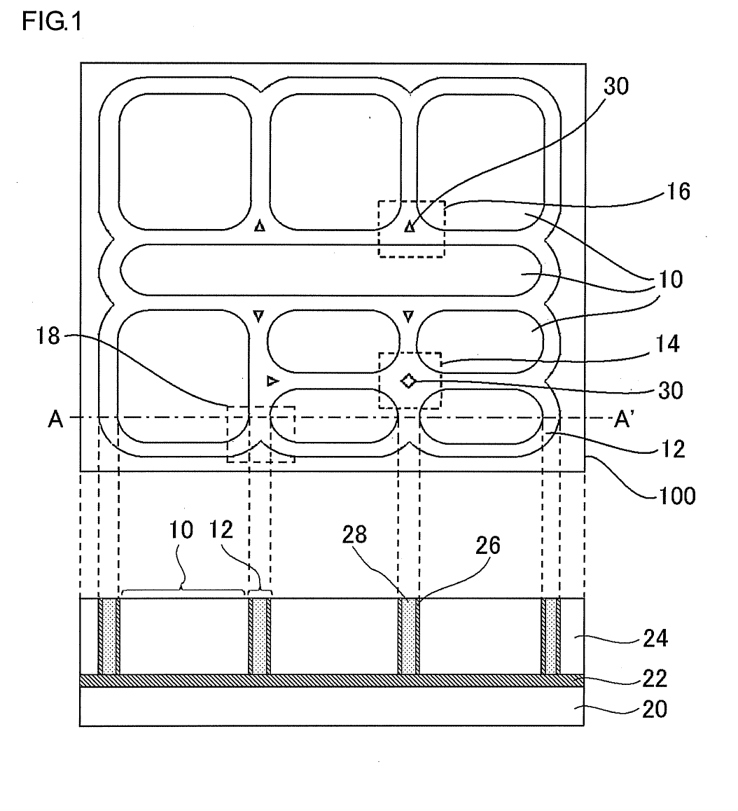

FIG. 1 shows one chip pattern and a cross section taken along the dashed-dotted line A-A′ when element isolating insulation films are formed on an SOI substrate by the DTI method in a present embodiment. A chip pattern 100 includes an element isolating insulation film 12 and a plurality of Si regions 10 separated by the element isolating insulation film. In addition, the chip pattern shown in FIG. 1 is exemplification, it is understood by those skilled in the art that there are various cases depending on desired element arrangements.

As shown in the cross-sectional view of the chip pattern 100, the element isolating insulation film 12 is formed by forming an SiO₂ film 26 on an inner wall of a trench formed on the SOI substrate in which an Si layer 20, an insulation layer 22, and an active region Si layer 24 are laminated; and by further embedding the trench with Poly-Si 28. With this configuration, the Si region 10 is in a state in which a bottom surface thereof is surrounded by the insulation layer 22, and side surfaces thereof are surrounded by the element isolating insulation film 12. An element such as a transistor is formed in the Si region 10; and accordingly, each element can be operated without receiving influence from other Si region 10.

However, if the element isolating insulation films 12 in the same chips are made large and small in width, the following defect tends to take place. That is, a place which is narrow in width needs to be formed with a trench having a high aspect ratio, and the bottom of the trench becomes difficult to reach the insulation layer 22 as compared with a place which is wide in width. As a result, it tends to generate a state that the Si region 10 is not completely insulated. On the other hand, the place which is wide in width tends not to be sufficiently embedded with the Poly-Si 28 to generate a concave at an upper part of the element isolating insulation film 12; and consequently, there is a possibility to exert influence on formation of the upper layer. Such features result in narrowing a permissible margin of processing dimensions and therefore a processing window in a process of forming the element isolating insulation film 12.

Consequently, in the present embodiment, the widths of the element isolating insulation films 12 are the same in the chip pattern 100. In this case, the terminology of “the same” may include a processing error which is generally present. In order to make the widths of the element isolating insulation films 12 uniform, as shown in the drawing, curved line portions where the element isolating insulation films 12 separate into two directions are provided in a portion 14 where the element isolating insulation films 12 are intersected in a cross shape, and in a portion 16 where the element isolating insulation films 12 are intersected in a T shape. As a result, it becomes a state that a minute Si region 30 remains at the center of the intersecting portion. Alternatively, when there are not the adjacent Si regions 10, as shown in a portion 18 intersected in a T shape, only curved lines to be separated are provided. A permissible margin of the processing dimensions increases and the processing window broadens by making the widths of the element isolating insulation films 12 uniform at a designing stage.

In addition, the portion where the element isolating insulation films 12 separate into two directions is not limited to a curved line; but, the portion may be made by a broken line, and both of the curved line and the broken line may be included. For example, when the aforementioned portion is designed by applying a part of sides of a polygon having approximately not less than 24 sides, a shape to be substantially a curved line can be obtained depending on processing accuracy in forming the trench. The curved line portion may be actually formed in such a manner. In addition, even when the shape of the sides of the polygon is remained, the same effect as the case of the curved line can be obtained. The following description including such embodiment will be described as a curved line.

Further, in the present embodiment, the Si region 10 has a shape composed of straight lines which form four sides and circular arcs which form four corners. Further, the adjacent Si regions 10 share the element isolating insulation film 12, and the adjacent Si regions are separated by one element isolating insulation film 12. By forming such pattern, the chip area can be reduced by two reasons to be described below.

First, the Si region 10 is formed to be a shape having no corners; and accordingly, there can be dispersed a stress due to a repulsive force between oxygen atoms, the stress being generated when the SiO₂ film 26 of the element isolating insulation film 12 is formed. This makes various problems posed by a generation of a local stress, that is, a generation of a crystal defect, a variation in resistance value due to fluctuation of carrier mobility, an increase in leakage, a decrease in breakdown voltage, and the like difficult to cause; and therefore, it becomes difficult to receive a bad influence even when elements are formed relatively adjacent to the element isolating insulation film 12. Therefore, an interval between the element isolating insulation film 12 and the element can be narrowed and wasted regions can be reduced.

Furthermore, only one element isolating insulation film 12 is formed between the adjacent Si regions 10; and therefore, an area for the element isolating insulation films 12 and an area of a region between the adjacent element isolating insulation films 12 can be reduced as compared with the case where the element isolating insulation films 12 are separately formed at each outer circumference of the Si regions 10.

Additionally, the Si region 10 is formed to be the shape having no corners; and accordingly, a distance between the transistor formed in the Si region 10 and the element isolating insulation film 12 can be efficiently ensured. This is effective with respect to reduction in the chip area mentioned above; and further, a distance necessary for not exceeding dielectric breakdown field strength of Si even when a high voltage is applied to the transistor can be effectively gained. As a result, a high breakdown voltage device can be manufactured without increasing the chip area.

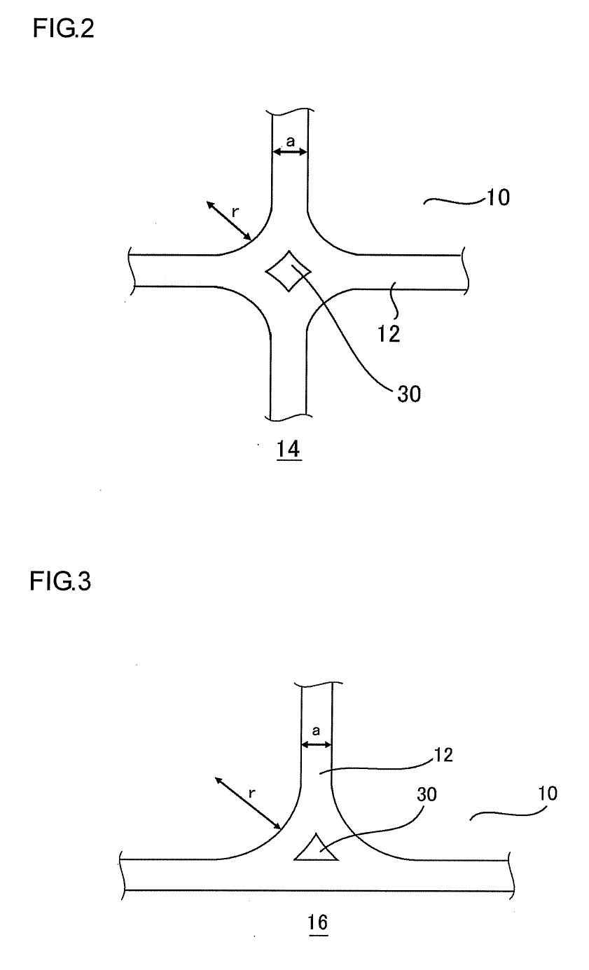

Next, a rule at the time of designing the chip pattern 100 will be described. FIG. 2 is an enlarged view showing the portion 14 in which the element isolating insulation films 12 intersect in the cross shape. As described above, the element isolating insulation films 12 have the same widths; and therefore, it becomes a state that the minute Si region 30 remains at the center of the intersecting portion 14. In this case, when a width of the element isolating insulation film 12 is set to a, and a curvature radius of a part of circumference which form four corners of the Si region 10 is set to r; the width a and the curvature radius r are determined so as to be r>0.7a. Under such rule, however hard the width a may be set, the minute Si region 30 is formed; and there can be formed the element isolating insulation film 12 whose width is always constant even in the portion 14 intersected in the cross shape.

FIG. 3 is an enlarged view showing the portion 16 in which the element isolating insulation films 12 intersect in the T shape. Also in this case, the minute Si region 30 is remained at the center as in the portion 14 intersected in the cross shape. In this case, a width a and a curvature radius r are determined so as to be r>1.5a. A width a and a curvature radius r of the portion 18 intersected in the T shape having a shape in which the outer circumference is along the inner circumference without forming the minute Si region 30 at a chip end or the like are also determined by the same rule. Also in this case, as in the portion 14 intersected in the cross shape, the curvature radius r is determined by such rule; and accordingly, the element isolating insulation film 12 whose width is always constant can be formed however hard the width a may be set.

In the present embodiment, the Si region 10 is formed to be the shape having no corners; and accordingly, parameters to be determined with respect to the width a of the element isolating insulation film 12 can be only the curvature radius r. In the case of an arrangement including both the portion 14 intersected in the cross shape and the portion 16 or 18 intersected in the T shape, the rule in the T shape is prioritized to be r>1.5a. A pattern of the element isolating insulation film 12 with uniform width can be automatically obtained by merely determining r in accordance with the rule in such a manner; and therefore, it is not necessary to calculate the size and arrangement of the minute Si region 30, and designing of the pattern is easy.

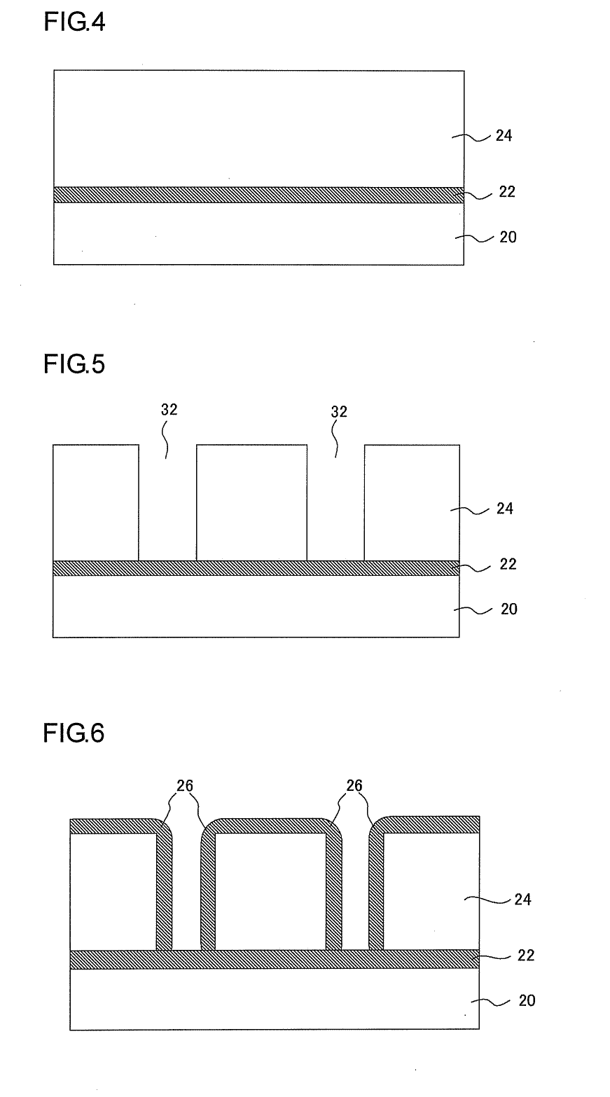

Next, a method of manufacturing a chip pattern 100 will be described. First, as shown in FIG. 4, there is provided an SOI substrate laminated in the order corresponding to an Si layer 20, an insulation layer 22, and an active region Si layer 24. Next, as shown in FIG. 5, a trench 32 is formed by etching the active region Si layer 24 to the insulation layer 22 by the RIE. A width of the trench at this time is approximately 1.0 to 3.0 μm, for example.

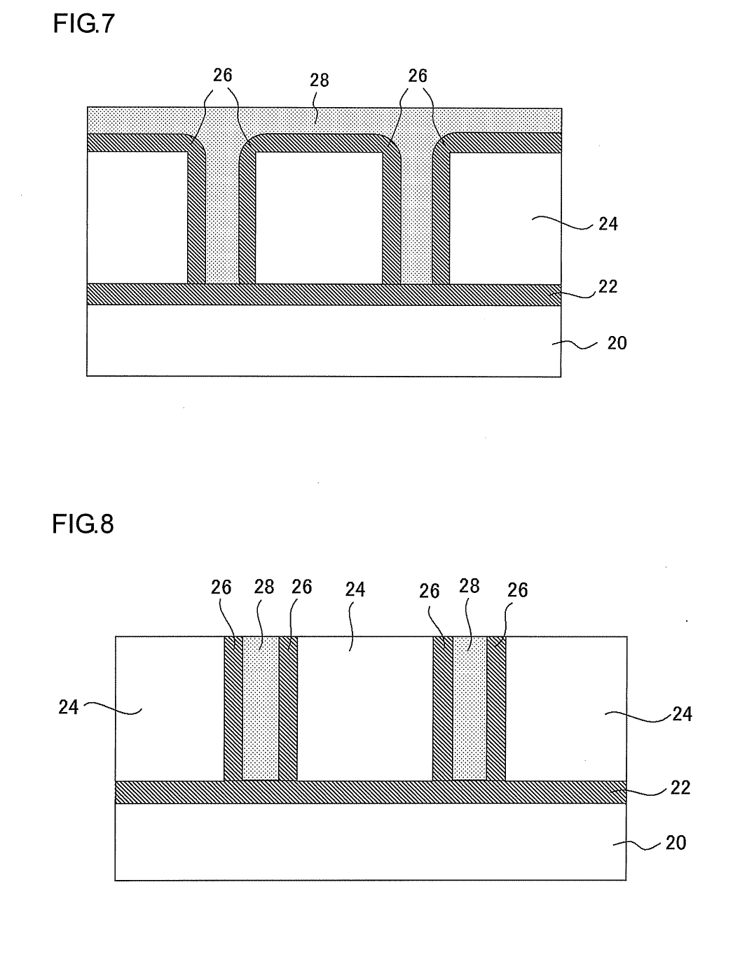

Next, as shown in FIG. 6, an SiO₂ film 26 having approximately 0.4 to 0.6 μm is formed in an inner wall or the like of the trench 32 by the thermal oxidation or the chemical vapor deposition (referred to as CVD) method. Then, as shown in FIG. 7, Poly-Si 28 is embedded inside the trench 32 by performing a vapor phase growth by the CVD method; and then, as shown in FIG. 8, etch back is applied and an upper surface of the active region Si layer 24 is planarized.

When the chip pattern 100 formed in the above manner is compared with a pattern in which individual element isolating insulation film is formed for each Si region, a chip area can be reduced by approximately 5 to 10% in a scan driver having the same configuration.

As described above, according to the present embodiment, an element isolating insulation film is formed to be a pattern having no corners, and one element isolating insulation film is shared between adjacent Si regions. With this configuration, a distance between an element and the element isolating insulation film can be narrowed, by dispersing a stress generated when the element isolating insulation film is formed to uniformize an electrical characteristic of the active region Si, and an interval of the adjacent Si regions can be narrowed; and as a result, the chip area can be significantly reduced. In addition, even when the size of the pattern of the element isolating insulation film is shrunk, a distance with the element can be efficiently ensured as compared with the pattern in which corners are included in the element isolating insulation film; and therefore, a high voltage can be applied to a transistor without causing dielectric breakdown of Si, and a high breakdown voltage semiconductor device can be realized while suppressing the chip area.

Further, an element isolating insulation film pattern having the same width can be obtained at any place in the chip by merely determining a curvature radius of curved lines constituting four corners in accordance with a predetermined rule with respect to the width of the element isolating insulation film. Although there is a possibility that the Si region is not insulated or the upper surface does not become flat due to a shortage of embedding Poly-Si depending on the width of the element isolating insulation film, a processing window can be broadened by setting the width to be the same at a designing stage. As a result, a pattern design with a wide processing window can be easily performed.

As described above, the present invention is described based on the embodiment. It is to be understood to those skilled in the art that the above embodiment is an exemplification, various modifications are possible in the combination of their respective constituent elements, and such modifications fall within the scope of the present invention.

For example, the present embodiment describes about the pattern of the element isolating insulation film; however, the same embodiment can be applied to an interconnect line pattern. In interconnect line, there is a case that etching speed varies or embeddedness of the material for interconnect is insufficient depending on the aspect ratio. Depending on the shape of interconnection, the processing window can be broadened by setting the pattern on the basis of the same rule as the present embodiment.

Furthermore, in the present embodiment, the bottom surface of the Si region is made of the insulation layer using the SOI substrate; however, there can be a configuration that includes a p-type or an N-type embedded layer in place of the insulation layer. Also in this case, the same effects as those of the present embodiment, such as reduction in chip area and increase in processing window, can be obtained by the easy design procedure.

While the preferred embodiments of the present invention have been described using specific terms, such description is for illustrative purposes only, and it is to be understood that changes and variations may be made without departing from the spirit or scope of the appended claims.

What is claimed is:

1. A semiconductor integrated circuit, comprising:
a trench; and
a layer provided with an embedded line in which a predetermined material is embedded in the trench, wherein
the embedded line has a predetermined same width and a pattern including portions which intersect each other, and
the embedded line in the intersecting portions includes at least either a curved line portion or a broken line portion which makes one embedded line separate into two directions.

2. The semiconductor integrated circuit according to claim 1, wherein
the embedded line is made up of an element isolating insulation film which insulatively separates a substrate for each predetermined region; and
the adjacent regions are insulatively separated by one element isolating insulation film.

3. The semiconductor integrated circuit according to claim 1, wherein
a bottom surface of the embedded line is an insulation layer in an SOI substrate laminated in the order corresponding to an Si layer, the insulation layer, and an active region Si layer; and
the embedded line is composed of an insulation film which insulatively separates the active region Si layer.

4. The semiconductor integrated circuit according to claim 1, wherein
the embedded line has a two layer configuration composed of an SiO₂ layer and a Poly-Si layer.

5. The semiconductor integrated circuit according to claim 2, wherein
the region has four corners surrounded by the embedded lines, each of which being formed by either the curved line or the broken line.

6. The semiconductor integrated circuit according to claim 1, wherein
when the embedded line in the intersecting portion includes the curved line portion, the curved line portion has a circular arc shape, a width of the embedded line is set to a, and an inner curvature radius of the curved line portion is set to r; and
when the pattern of the embedded line includes a portion intersected in a T shape, a condition of r>1.5a is satisfied.

7. The semiconductor integrated circuit according to claim 1, wherein
when the embedded line in the intersecting portion includes the curved line portion, the curved line portion is a part of a circular arc, a width of the embedded line is set to a, and an inner curvature radius of the curved line portion is set to r; and
when the pattern of the embedded line intersects only in a cross shape, a condition of r>0.7a is satisfied.

8. The semiconductor integrated circuit according to claim 1, wherein
when the embedded line in the intersecting portion includes the broken line portion, the broken line portion is a part of sides of a polygon having not less than 24 sides.
